(19) United States
(12) Patent Application Publication
(10) Pub. No.: US 2026/0114302 A1
(43) Pub. Date: Apr. 23, 2026

(54) SEMICONDUCTOR PACKAGE

(71) Applicant: Samsung Electronics Co., Ltd., Suwon-si (KR)

(72) Inventors: Jeon Il LEE, Suwon-si (KR); Jinwoo HAN, Suwon-si (KR)

(73) Assignee: Samsung Electronics Co., Ltd., Suwon-si (KR)

(21) Appl. No.: 19/336,803

(22) Filed: Sep. 23, 2025

(30) Foreign Application Priority Data
Oct. 22, 2024 (KR) 10-2024-0145155

(51) Int. Cl. H01L 23/498; H01L 23/28; H01L 23/48; H01L 25/065; H01L 25/10

(52) U.S. Cl. CPC H10W 70/635; H10W 20/20; H10W 74/00; H10W 90/00; H10W 72/823

(57) ABSTRACT

A semiconductor package according to some example embodiments includes a substrate, a first semiconductor chip and a plurality of memory structures on the substrate, and a through via penetrating at least one of the plurality of memory structures. The plurality of memory structures are stacked in a vertical direction, the vertical direction being perpendicular to an upper surface of the substrate, each of the plurality of memory structures includes a buffer die, a plurality of memory dies stacked on the buffer die, and a molding member covering the buffer die and the plurality of memory dies, and the through via includes a mold through via that penetrates the molding member.

### CROSS-REFERENCE TO RELATED APPLICATION

This application claims priority to and the benefit of Korean Patent Application No. 10-2024-0145155 filed in the Korean Intellectual Property Office on Oct. 22, 2024, the entire contents of which are incorporated herein by reference.

### BACKGROUND

Example embodiments of the present disclosure relate to a semiconductor package.

As the scaling of artificial neural network models increases, there is continuous demand for increasing capacity and bandwidth of high bandwidth memory (HBM). Additionally, as the number of memory dies connected to one buffer die in the HBM increases and as the number of stacked memory dies increases, bottlenecks may occur in the device, thereby increasing the difficulty of bonding processes. Accordingly, packaging technology is being proposed to increase input/output (I/O) bandwidth between memory chips and logic chips and/or to overcome stacking limitations of HBM.

### SUMMARY

Some example embodiments are intended to provide a semiconductor package that can dramatically increase bandwidth.

A semiconductor package according to some example embodiments includes a substrate, a first semiconductor chip and a plurality of memory structures on the substrate, and a through via penetrating at least one of the plurality of memory structures. The plurality of memory structures are stacked in a vertical direction, the vertical direction being perpendicular to an upper surface of the substrate, each of the plurality of memory structures includes a buffer die, a plurality of memory dies stacked on the buffer die, and a molding member covering the buffer die and the plurality of memory dies, and the through via includes a mold through via that penetrates the molding member.

A semiconductor package according to some example embodiments includes a substrate, a first semiconductor chip on the substrate, a plurality of buffer dies and a plurality of memory dies on the substrate, such that at least two memory dies of the plurality of memory dies are stacked on one buffer die, a plurality of molding members stacked on the substrate, each molding member of the plurality of molding members covering one buffer die and at least two memory dies, and at least one mold through via penetrating each molding member of the plurality of molding members except for an uppermost molding member among the plurality of molding members.

A semiconductor package according to some example embodiments includes a substrate, a first semiconductor chip on the substrate, a plurality of memory structures stacked on the substrate, each memory structure including a buffer die, a plurality of memory dies stacked on the buffer die, and a molding member covering the buffer die and the plurality of memory dies, and a mold through via penetrating each molding member of the plurality of memory structures except for an uppermost memory structure among the plurality of memory structures. Each of the plurality of memory structures is electrically connected to the first semiconductor chip through the mold through via.

A method of operating a semiconductor package according to some example embodiments includes transmitting a first signal though a first signal path between a main interposer and a first memory structure; transmitting a second signal through a second signal path between the main interposer and a second memory structure; and transmitting a third signal through a third signal path between the main interposer and a third memory structure, wherein the first signal path is through a first interposer via, the second signal path is through a first mold through via and the first interposer via, the third signal path is through a second mold through via, a second interposer via, the first mold through via, and the first interposer via, the semiconductor package comprises a substrate, the main interposer on the substrate, a first semiconductor chip and a plurality of memory structures on the main interposer, the plurality of memory structures includes the first memory structure on the main interposer, the second memory structure on the first memory structure, and the third memory structure on the second memory structure, a through via penetrating at least one of the plurality of memory structures, each of the plurality of memory structures includes a sub-interposer, a buffer die on the sub-interposer, a plurality of memory dies on the buffer die, and a molding member covering the buffer die and the plurality of memory dies, the first interposer via penetrates the sub-interposer of the first memory structure and connects the main interposer to the first memory structure, the second interposer via penetrates the sub-interposer of the second memory structure and connects the second memory structure to the first memory structure, the first mold through via penetrates through the molding member of the first memory structure, and the second mold through via penetrates through the molding member of the second memory structure.

According to some example embodiments, in the method of operating a semiconductor package the first signal path, the second signal path, and the third signal path do not overlap.

According to some example embodiments, the bandwidth of semiconductor packages may be dramatically increased.

### BRIEF DESCRIPTION OF THE DRAWINGS

FIG. 1 is a cross-sectional view of a semiconductor package according to some example embodiments.

FIG. 2 is a cross-sectional view of a semiconductor package according to some example embodiments.

FIG. 3 is a cross-sectional view of a semiconductor package according to some example embodiments.

FIG. 4 is a top plan view of a semiconductor package seen from a level of a line A-A′ of FIG. 3.

FIG. 5 is a cross-sectional view of a semiconductor package according to some example embodiments.

FIG. 6 is a cross-sectional view of a semiconductor package according to some example embodiments.

FIG. 7 is a cross-sectional view of a semiconductor package according to some example embodiments.

FIG. 8 is a cross-sectional view of a semiconductor package according to some example embodiments.

### DETAILED DESCRIPTION

Some example embodiments of the present disclosure will be described more fully hereinafter with reference to the accompanying drawings, in which example embodiments of the disclosure are shown. As those skilled in the art would realize, the described example embodiments may be modified in various different ways, all without departing from the spirit or scope of the present disclosure.

Descriptions of parts not related to the present disclosure are omitted, and like reference numerals which designate like elements throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Further, throughout the specification, the phrase “on a plane” means viewing a target portion from the top, and the phrase “on a cross-section” means viewing a cross-section formed by vertically cutting a target portion from the side.

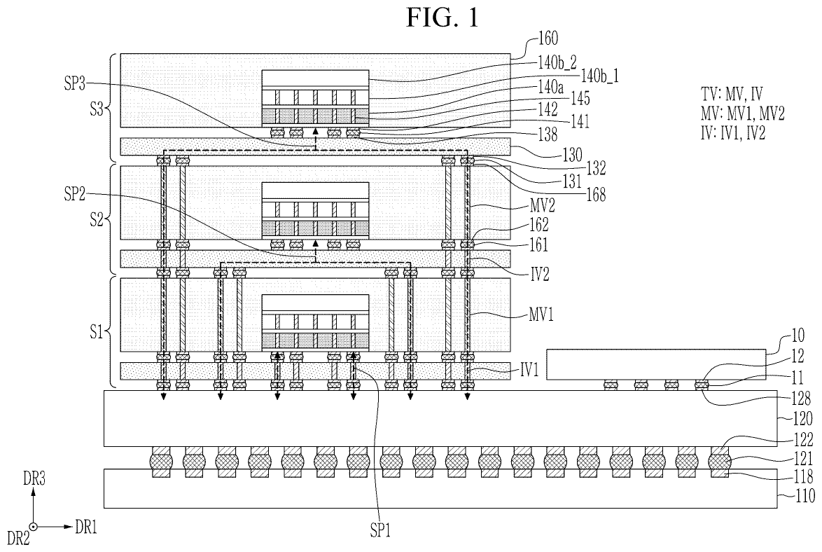

Below, a semiconductor package according to some example embodiments is described with reference to FIG. 1.

FIG. 1 is a cross-sectional view of a semiconductor package according to some example embodiments.

A semiconductor package according to some example embodiments may include a substrate 110, a first semiconductor chip 10 positioned on the substrate 110, a plurality of memory structures S1, S2, and S3, and a through vis TV penetrating the plurality of memory structures S1, S2, and S3.

In some example embodiments, the first semiconductor chip 10 and the plurality of memory structures S1, S2, and S3 may be arranged on the substrate 110 in a direction parallel to the upper surface of the substrate 110 (e.g., a first direction DR1). The plurality of memory structures S1, S2, and S3 may be stacked in a direction (e.g., a third direction DR3) vertical to the upper surface of the substrate 110.

In some example embodiments, the semiconductor package may include a main interposer 120 positioned between the substrate 110 and the first semiconductor chip 10, and between the substrate 110 and the plurality of memory structures S1, S2, and S3. The first semiconductor chip 10 and the plurality of memory structures S1, S2, and S3 may be arranged on the main interposer 120 in a direction (e.g., the first direction DR1) parallel to the upper surface of the main interposer 120. The plurality of memory structures S1, S2, and S3 may be stacked in the third direction DR3 on the main interposer 120.

The substrate 110 may be a substrate for a package, for example, a printed circuit board (PCB) or a ceramic substrate. If the substrate 110 is the printed circuit board (PCB), the substrate 110 may be made of at least one material selected from phenol resin, epoxy resin, and polyimide. However, example embodiments are not limited thereto. The substrate 110 may include an integrated circuit (IC). The substrate 110 may include one or more routing wires.

A plurality of first connection pads 118 may be positioned within the upper surface of the substrate 110. The plurality of first connection pads 118 may be spaced apart and arranged along the direction (e.g., the first direction DR1) parallel to the upper surface of the substrate 110. For example, the side of the plurality of first connection pads 118 may be surrounded by an insulation layer of the substrate 110. The upper surface of the plurality of first connection pads 118 may be positioned at substantially the same level as the upper surface of the substrate 110, but example embodiments are not limited thereto.

The first connection pad 118 may include a conductive material. For example, the first connection pad 118 may include a metal such as copper, aluminum, or an alloy thereof. However, example embodiments are not limited thereto. The plurality of first connection pads 118 may electrically connect components (e.g., the main interposer 120, the first semiconductor chip 10, and the plurality of memory structures S1, S2, and S3) positioned on the upper surface of the substrate 110 to the substrate 110.

The main interposer 120 may connect components positioned on the upper surface of the main interposer 120 to the substrate 110 and connect components positioned on the upper surface of the main interposer 120 to each other. Although not shown, the main interposer 120 may include wiring layers and/or through vias. A wiring layer of the main interposer 120 may include a wiring that connects the plurality of memory structures S1, S2, and S3 to the first semiconductor chip 10, and a wiring that connects each of the plurality of memory structures S2, S2, and S3 and the first semiconductor chip 10 to the substrate 110. The through-vias in the main interposer 120 may connect the plurality of memory structures S2, S2, and S3 and the first semiconductor chip 10 to the substrate 110, respectively.

A plurality of second connection pads 122 may be positioned on the lower surface of the main interposer 120, and a plurality of first connection members 121 may be respectively positioned on the plurality of second connection pads 122. The first connection member 121 may be positioned between the first connection pad 118 and the second connection pad 122. The main interposer 120 may be connected to the substrate 110 by the plurality of second connection pads 122 and the plurality of first connection members 121. The plurality of second connection pads 122 may be connected to the plurality of first connection pads 118 by the plurality of first connection member 121.

A plurality of third connection pads 128 may be positioned on the upper surface of the main interposer 120. The main interposer 120 may be connected to the first semiconductor chip 10 and the plurality of memory structures S1, S2, and S3 by the plurality of third connection pads 128. The plurality of third connection pads 128 may be connected to the plurality of second connection pads 122 via a wiring layer and/or a through via of the main interposer 120. At least one third connection pad 128 located under the plurality of memory structures S1, S2, and S3 among the plurality of third connection pads 128 may be connected at least one third connection pad 128 positioned below the first semiconductor chip 10. by the wiring layer of the main interposer 120. For example, the third connection pad 128 connected to the buffer die 140a and the plurality of memory dies 140b_1 and 140b_2 in the first memory structure S1 may be electrically connected to the third connection pad 128 connected to the first semiconductor chip 10. The third connection pad 128, which is electrically connected to the buffer die 140a and the plurality of memory dies 140b_1 and 140b_2 in the second memory structure S2 and is connected to the through via TV penetrating the first memory structure S1, may be electrically connected to the third connection pad 128, which is connected to the first semiconductor chip 10. The third connection pad 128, which is electrically connected to the buffer die 140a and the plurality of memory dies 140b_1 and 140b_2 within the third memory structure S3 and connected to the through via TV penetrating the second memory structure S2 and the first memory structure S1, may be electrically connected to the third connection pad 128, which is connected to the first semiconductor chip 10.

Each of the first connection member 121, the second connection pad 122, and the third connection pad 128 may include a conductive material. For example, the first connection member 121, the second connection pad 122, and the third connection pad 128 may each include a metal such as copper, aluminum, or an alloy thereof. For example, the first connection member 121 may be a solder ball.

The first semiconductor chip 10 may be a logic chip. The first semiconductor chip 10 may control the plurality of memory structures S1, S2, and S3. For example, the first semiconductor chip 10 may be a central processing unit (CPU), a graphic processing unit (GPU), a neural processing unit (NPU), a system on chip (SOC), an application processor (application processor), or an application specific integrated circuit (ASIC). The first semiconductor chip 10 may act as a host, but is not necessarily limited to this.

A plurality of fourth connection pads 12 may be positioned on the lower surface of the first semiconductor chip 10, and a plurality of second connection members 11 may be positioned on the plurality of fourth connection pads 12. The first semiconductor chip 10 may be connected to the main interposer 120 by the plurality of fourth connection pads 12 and the plurality of second connection members 11. The plurality of fourth connection pad 12 may be connected to some of the plurality of third connection pads 128 by the plurality of second connection members 11.

Each of the second connection member 11 and the fourth connection pad 12 may include a conductive material. For example, the second connection member 11 and the fourth connection pad 12 may each include a metal such as copper, aluminum, or an alloy thereof. However, example embodiments are not limited thereto. For example, the second connection member 11 may be a solder ball.

The plurality of memory structures S1, S2, and S3 may each be a memory chip. The plurality of memory structures S1, S2, and S3 may each store a data. Each of the plurality of memory structures S1, S2, and S3 may include a buffer die 140a, a plurality of memory dies 140b_1 and 140b_2 stacked on the buffer die 140a, and a molding member 160 covering the buffer die 140a and the plurality of memory dies 140b_1 and 140b_2.

In some example embodiments, each of the plurality of memory structures S1, S2, and S3 may include a sub-interposer 130. The buffer die 140a, the plurality of memory dies 140b_1 and 140b_2, and the molding member 160 may be positioned on the sub-interposer 130. The buffer die 140a and the plurality of memory dies 140b_1 and 140b_2 may be stacked on the sub-interposer 130 in a direction (e.g., the third direction DR3) vertical to the upper surface of the sub-interposer 130. The planar area of the sub-interposer 130 may be wider than the planar areas of the buffer die 140a and the plurality of memory dies 140b_1 and 140b_2.

The plurality of fifth connection pads 132 may be positioned on the lower surface of the sub-interposer 130, and the plurality of third connection members 131 may be positioned on the plurality of fifth connection pads 132. The sub-interposer 130 may be connected to components positioned below the sub-interposer 130 by the plurality of fifth connection pads 132 and the plurality of third connection members 131. A plurality of sixth connection pads 138 may be positioned on the upper surface of the sub-interposer 130. The sub-interposer 130 may be connected to a component positioned above the sub-interposer 130 by the plurality of sixth connection pads 138.

Each of the third connection member 131, the fifth connection pad 132, and the sixth connection pad 138 may include a conductive material. For example, the third connection member 131, the fifth connection pad 132, and the sixth connection pad 138 may each include a metal such as copper, aluminum, or an alloy thereof. However, example embodiments are not limited thereto. For example, the third connection member 131 may be a solder ball.

The buffer die 140a may be a logic die. The buffer die 140a may include a circuitry that is electrically connected to the first semiconductor chip 10 and controls the overall operation of the plurality of memory dies 140b_1 and 140b_2.

A plurality of buffer lower pads 142 may be positioned on the lower surface of the buffer die 140a, and a plurality of buffer connection members 141 may be positioned on the plurality of buffer lower pads 142. In some example embodiments, the buffer die 140a of each of the plurality of memory structures S1, S2, and S3 may be connected to the sub-interposers 130 of each of the plurality of memory structures S1, S2, and S3 by the plurality of buffer lower pads 142 and the plurality of buffer connection members 141. The plurality of buffer lower pads 142 may be connected to some of the plurality of sixth connection pads 138 positioned on the upper surface of the sub-interposer 130 by the plurality of buffer connection members 141.

Each of the buffer connection member 141 and the buffer lower pad 142 may include a conductive material. For example, each of the buffer connection member 141 and the buffer lower pad 142 may include a metal such as copper, aluminum, or an alloy thereof. However, example embodiments are not limited thereto. For example, the buffer connection member 141 may be a solder ball.

The plurality of memory dies 140b_1 and 140b_2 may each be a dynamic random access memory (DRAM), but example embodiments are not limited thereto. The plurality of memory dies 140b_1 and 140b_2 may include the same type of memory dies, but may also include a mixture of different types of memory dies.

FIG. 1 illustrates that each of the plurality of memory structures S1, S2, and S3 includes two memory dies 140b_1 and 140b_2, but the number of memory dies in each of the plurality of memory structures S1, S2, and S3 is not limited thereto and may vary.

Each of the plurality of memory structures S1, S2, and S3 may include a die through via 145 penetrating at least one of the buffer die 140a and the plurality of memory dies 140b_1 and 140b_2. The plurality of memory dies 140b_1 and 140b_2 may be connected to the buffer die 140a by the die through via 145.

The plurality of memory dies 140b_1 and 140b_2 are stacked in the vertical direction to the upper surface of the buffer die 140a, and the plurality of memory dies 140b_1 and 140b_2 and the buffer die 140a are connected in the vertical direction by the die through via 145, so that each of the plurality of memory structures S1, S2, and S3 may have a high bandwidth characteristic and a high-speed characteristic.

In some example embodiments, the molding member 160 may cover the side surfaces of the buffer die 140a and the plurality of memory dies 140b_1 and 140b_2. The molding member 160 may surround the side surfaces of the buffer die 140a and the plurality of memory dies 140b_1 and 140b_2. The molding member 160 may cover the upper surfaces of the buffer die 140a and the plurality of memory dies 140b_1 and 140b_2, but example embodiments are not limited thereto. The molding member 160 may protect the buffer die 140a and the plurality of memory dies 140b_1 and 140b_2.

For example, the molding member 160 may include a thermosetting resin such as an epoxy resin, a thermoplastic resin such as a polyimide, a resin including inorganic fillers and/or glass fibers, or an epoxy molding compound (EMC).

In some example embodiments, a plurality of mold lower pads 162 may be positioned on the lower surface of the molding member 160, and a plurality of mold connection members 161 may be positioned on the plurality of mold lower pads 162. A plurality of mold upper pads 168 may be positioned on the upper surface of the molding member 160. In some example embodiments, the plurality of mold lower pads 162, the plurality of mold connection members 161, and the plurality of mold upper pads 168 may not be positioned on the upper and lower surfaces of the molding members 160 of the uppermost memory structure of the plurality of memory structures S1, S2, and S3.

In some example embodiments, the plurality of mold lower pads 162 and the plurality of mold connection members 161 of the certain memory structure may be connected to the sub-interposer 130 of the corresponding memory structure. The plurality of mold lower pads 162 of the certain memory structure may be connected to a portion of the plurality of sixth connection pads 138 positioned on the upper surface of the sub-interposer 130 of the corresponding memory structure by the plurality of mold connection members 161.

In some example embodiments, the plurality of mold upper pads 168 of the certain memory structure may be connected to the sub-interposer 130 of the memory structure positioned above the corresponding memory structure. The plurality of mold upper pads 168 of the certain memory structure may be connected to the plurality of fifth connection pads 132 and the plurality of third connection members 131 positioned on the lower surface of the sub-interposer 130 of the memory structure positioned above the corresponding memory structure.

In some example embodiments, the plurality of mold upper pads 168 and the plurality of mold lower pads 162 of the certain memory structure may be connected to each other by through-mold vias MV as described below.

Each of the mold connection member 161, the mold lower pad 162, and the mold upper pad 168 may include a conductive material. For example, each of the mold connection member 161, the mold lower pad 162, and the mold upper pad 168 may include a metal such as copper, aluminum, or an alloy thereof. However, example embodiments are not limited thereto. For example, the mold connection member 161 may be a solder ball.

In some example embodiments, the plurality of memory structures S1, S2, and S3 may include a first memory structure S1, a second memory structure S2, and a third memory structure S3 sequentially stacked on the substrate 110 or the main interposer 120. In the example of FIG. 1, the first memory structure S1 may be the lowermost memory structure among the plurality of memory structures S1, S2, and S3. The third memory structure S3 may be the uppermost memory structure among the plurality of memory structures S1, S2, and S3. The second memory structure S2 may be the intermediate memory structure positioned between the lowermost memory structure and the uppermost memory structure among the plurality of memory structures S1, S2, and S3. Although FIG. 1 illustrates that three memory structures S1, S2, and S3 are stacked, the number of the plurality of memory structures S1, S2, and S3 stacked on the substrate 110 may vary.

In some example embodiments, the through vias TV penetrating the plurality of memory structures S1, S2, and S3 may include a mold through via MV penetrating the molding member 160. The mold through via MV may penetrate the remaining memory structures except for the uppermost memory structure among the plurality of memory structures S1, S2, and S3. For example, the mold through via MV may penetrate the first memory structure S1 and the second memory structure S2, excluding the third memory structure S3. The mold through via MV may connect the mold lower pad 162 and the mold upper pad 168, which are positioned on the lower surface and the upper surface of the molding member 160 through which the mold through via MV penetrates, respectively, in the direction (e.g., the third direction DR3) vertical to the upper surface of the substrate 110.

The mold through via MV may include a conductive material. For example, the mold through via MV may include a metal such as copper, aluminum, or an alloy thereof. In some example embodiments, the mold through via MV may electrically connect the sub-interposers 130 positioned above and below the molding member 160 through which the mold through via MV penetrates. The mold through via MV may electrically connect the sub-interposer 130 of the memory structure through which the mold through via MV penetrates and the sub-interposer 130 of the memory structure positioned above the memory structure.

In some example embodiments, a plurality of mold through via MVs may be provided penetrating one molding member 160. Each of the plurality of molds through via MV penetrating one molding member 160 may be electrically connected to at least one memory structure positioned on the memory structure through which the plurality of mold through via MV penetrate. That is, each of the plurality of mold through via MVs penetrating one molding member 160 is not shared by multiple memory structures, but may only be used by one memory structure. That is, the plurality of mold through via MVs penetrating one molding member 160 may transmit and receive signals of each memory structure positioned above the memory structure through which the plurality of mold through vias MV penetrate in parallel at one time.

In some example embodiments, a plurality of mold through via MVs may be provided, each of which penetrates the plurality of molding members 160. For example, the plurality of mold through via MV may include a first mold through via MV1 penetrating the molding member 160 of the first memory structure S1 and a second mold through via MV2 penetrating the molding member 160 of the second memory structure S2. In some example embodiments, the number of the first mold through via MV1 may be greater than the number of the second mold through via MV2. For example, a plurality of first molds through via MV1 and a plurality of second molds through via MV2 may be provided. The plurality of second molds through vias MV2 may be connected to the third memory structure S3. The plurality of first mold through via MV1 may have some of the plurality of first mold through via MV1 connected to the second memory structure S2, and others connected to the third memory structure S3.

In some example embodiments, the second mold through via MV2 may be aligned to the first mold through via MV1 in a direction (e.g., the third direction DR3) perpendicular to the upper surface of the substrate 110. In some example embodiments, the second mold through via MV2 and the first mold through via MV1 connected to the same memory structure may be aligned in a direction (e.g., the third direction DR3) Perpendicular to the upper surface of the substrate 110. For example, the first mold through via MV1 and the second mold through via MV2 connected to the third memory structure S3 may be aligned in the vertical direction (e.g., the third direction DR3) to the upper surface of the substrate 110.

In some example embodiments, the through via TV penetrating the plurality of memory structures S1, S2, and S3 may further include an interposer through via IV penetrating the sub-interposer 130. The interposer through via IV may connect a fifth connection pad 132 positioned on the lower surface of the sub-interposer 130 and a sixth connection pad 138 positioned on the upper surface of the sub-interposer 130 in a vertical direction the (e.g., third direction DR3) to the upper surface of the substrate 110.

The interposer through via IV may include a conductive material. For example, the interposer through via IV may include a metal such as copper, aluminum, or an alloy thereof. In some example embodiments, the interposer through via IV may electrically connect the mold through vias MV that are spaced apart in the vertical direction (e.g., the third direction DR3) to the upper surface of the main interposer 120. The interposer through via IV may electrically connect the lowermost mold through via MV to the main interposer 120. The interposer through via IV may electrically connect the buffer die 140a and the plurality of memory dies 140b_1 and 140b_2 of the lowermost memory structure to the main interposer 120.

In some example embodiments, the interposer through via IV may include a first interposer through via IV1 penetrating the sub-interposer 130 of the first memory structure S1 and a second interposer through via IV2 penetrating the sub-interposer 130 of the second memory structure S2. Although not shown, the interposer through via IV may include a third interposer through via that penetrates the sub-interposer 130 of the third memory structure S3.

In some example embodiments, a plurality of interposers through vias IV that penetrate one sub-interposer 130 may be provided. For example, a plurality of first interposers through via IV1 and a plurality of second interposers through via IV2 may be provided. Each of the plurality of interposer through vias IV penetrating the single sub-interposer 130 may be electrically connected to one of at least one memory structure positioned above the memory structure through which the plurality of interposer through vias IV penetrate. That is, each of the plurality of interposer through vias IV penetrating one sub-interposer 130 is not shared by the multiple memory structures, but may only be used by one memory structure. That is, the plurality of interposer through vias IV penetrating one sub-interposer 130 may transmit and receive signals of each memory structure positioned above the memory structure penetrated by the plurality of interposer through vias IV in parallel.

In some example embodiments, at least one interposer through via IV may be aligned to the mold through via MV in the direction (for example, the third direction DR3) vertical to the upper surface of the substrate 110. At least one interposer through via IV may be aligned in the third direction DR3 with the mold through via MV positioned upper and/or lower than the sub-interposer 130 through which the interposer through via IV penetrates. The alignment of the interposer through via IV and the mold through via MV along the third direction DR3 may mean, for example, that the central axis of the interposer through via IV and the central axis of the mold through via MV along the third direction DR3 are approximately aligned.

In some example embodiments, at least one interposer through via IV may connect the mold through vias MV that are spaced apart in the direction (e.g., the third direction DR3). perpendicular to the upper surface of the main interposer 120. For example, the first mold through via MV1 and the second mold through via MV2 may be separated by the third direction DR3, and at least one second interposer through via IV2 may connect the first mold through via MV1 and the second mold through via MV2, which are separated in the third direction DR3. At least one second interposer through via IV2 may be aligned in the third direction DR3 with the first mold through via MV1 and the second mold through via MV2 connected by the second interposer through via IV2.

In some example embodiments, at least one interposer through via IV may connect the lowermost mold through via among the plurality of mold through via MVs and the main interposer 120. For example, among the first mold through via MV1 and the second mold through via MV2, the first mold through via MV1 may be positioned at the lowermost position, and at least one first interposer through via IV1 may connect the first mold through via MV1 and the main interposer 120. At least one first interposer through via IV1 may be aligned in the third direction DR3 with the first mold through via MV1 connected to the substrate 110 by the first interposer through via IV1.

In some example embodiments, the lowermost memory structure among the plurality of memory structures S1, S2, and S3 may be connected to the main interposer 120 by the interposer through via IV. At least one interposer through via IV may be positioned between the lower surface of the buffer die 140a of the lowermost memory structure and the upper surface of the main interposer 120. At least one interposer through via IV may connect the buffer die 140a and the plurality of memory dies 140b_1 and 140b_2 of the lowermost memory structure to the main interposer 120. For example, the first memory structure S1 may be connected to the main interposer 120 through at least one first interposer via IV1. At least one first interposer through via IV1 may be positioned between the lower surface of the buffer die 140a of the first memory structure S1 and the upper surface of the main interposer 120. At least one first interposer through via IV1 may connect the buffer die 140a and the plurality of memory dies 140b_1 and 140b_2 of the first memory structure S1, and the main interposer 120.

Although not shown, each of the sub-interposer 130 of the plurality of memory structures S1, S2, and S3 may include a wiring layer. The wiring layer of the sub-interposer 130 may connect the plurality of fifth connection pads 132 positioned on the lower surface of the sub-interposer 130 and the plurality of sixth connection pads 138 positioned on the upper surface of the sub-interposer 130.

Referring to the first signal path SP1, a signal may be transmitted/received between the main interposer 120 and the first memory structure S1 through the first interposer via IV1. Referring to the second signal path SP2, a signal may be transmitted/received between the main interposer 120 and the second memory structure S2 through the first mold via MV1 and the first interposer via IV1. Referring to the third signal path SP3, a signal may be transmitted/received between the main interposer 120 and the third memory structure S3 through the second mold via MV2, the second interposer via IV2, the first mold via MV1, and the first interposer via IV1. Signals transmitted to the main interposer 120 may be transmitted to the first semiconductor chip 10 or the substrate 110 through the wiring layer and/or the through via of the main interposer 120.

According to some example embodiments, the first signal path SP1, the second signal path SP2, and the third signal path SP3 may not overlap. As described above, each mold through via MV and each interposer through via IV may be connected to only one of the plurality of memory structures. That is, the mold through via MV and the interposer through via IV used in the first signal path SP1, the mold through via MV and the interposer through via IV used in the second signal path SP2, and the mold through via MV and the interposer through via IV used in the third signal path SP3 may not overlap with each other. Accordingly, the plurality of memory structures S1, S2, and S3 may communicate in parallel with the first semiconductor chip 10, and the bandwidth of the semiconductor package may be dramatically increased.

The semiconductor package according to some example embodiments includes the plurality of memory structures S1, S2, and S3 stacked on the main interposer 120, each of the plurality of memory structures S1, S2, and S3 includes one buffer die 140a, at least two memory dies 140b_1 and 140b_2, and the molding member 160 covering one buffer die 140a and at least two memory dies 140b_1 and 140b_2, and the plurality of memory structures S1, S2, and S3 may be connected to the main interposer 120 by the mold through via MV penetrating the molding member 160.

According to some example embodiments, the semiconductor package may include a plurality of buffer dies. Accordingly, the performance of the semiconductor package may be improved.

According to some example embodiments, the number of the memories stacked on the plurality of buffer dies may be reduced compared to a comparative example, which includes a single high bandwidth memory with a plurality of memory dies stacked on a single buffer die. For example, the difficulty of a bonding process for stacking the plurality of memory dies may increase as the number of the memory dies increases. Additionally, the difficulty of the process of bonding the relatively large memory structure may be lower than that of bonding the memory die. According to some example embodiments, the difficulty of the bonding process may be reduced compared to the comparative example.

Additionally, in the comparative example, a plurality of dies are connected to an interposer by through vias penetrating the die, and as the number of the through vias increases, the size (or the area) of the die increases. On the other hand, in the example embodiment, since the plurality of memory structures may be connected to the main interposer 120 by the mold through via MVs penetrating the molding member 160, even if the number of the mold through via MVs increases, the size (or the area) of the die does not increase, but only the size (or the area) of the main interposer 120 increases. Since a unit cost of the interposer is generally lower than that of the die, the production cost of the semiconductor package may be reduced, according to some example embodiments. Also, in the comparative example, all memory dies are connected to each through via.

According to some example embodiments, since each mold through via MV is connected to one memory structure, and the number of the memory dies included in one memory structure is less than that of the comparative example, the plurality of memory structures S1, S2, and S3 may communicate in parallel with the memory controller (e.g., the first semiconductor chip 10) and enable high-speed communication. According to some example embodiments, the bandwidth of the semiconductor package may be increased and/or the communication speed of the semiconductor package may be improved.

Further, in some example embodiments, each of the plurality of buffer die 140a may include a processing unit (e.g., an NPU), and each processing unit may perform some operation. The plurality of memory structures S1, S2, and S3 may each perform the operations in parallel by the processing unit of each buffer die 140a, so they may be used for a large amount of artificial neural network operations.

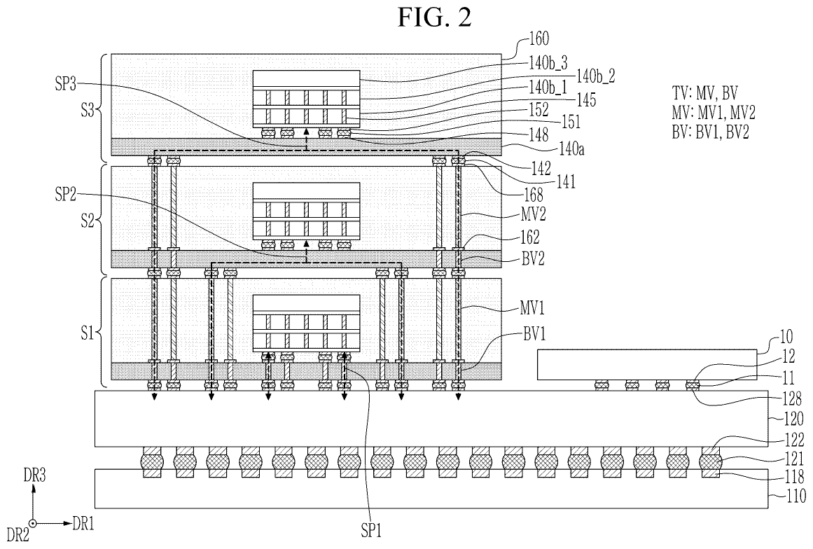

Below, variations of the semiconductor package according to the example embodiment of FIG. 1 are described with reference to FIG. 2.

FIG. 2 is a cross-sectional view of a semiconductor package according to some example embodiments. The example embodiment illustrated in FIG. 2 is substantially the same as the example embodiment illustrated in FIG. 1, so the description thereof will be omitted and the differences will be mainly explained. Additionally, the same reference numerals are used for the same components as in the previous embodiment. The example embodiment illustrated in FIG. 2 may differ from the previous embodiment in that the sub-interposer 130 is omitted in each of the plurality of memory structures S1, S2, and S3.

As shown in FIG. 2, the semiconductor package according to some example embodiments may include a substrate 110, a main interposer 120 positioned on the substrate 110, a first semiconductor chip 10 positioned on the main interposer 120, and a plurality of memory structures S1, S2, and S3. In some example embodiments, each of the plurality of memory structures S1, S2, and S3 may include a buffer die 140a, a plurality of memory dies 140b_1, 140b_2, and 140b_3 stacked on the buffer die 140a, and a molding member 160 covering the buffer die 140a and the plurality of memory dies 140b_1, 140b_2, and 140b_3. In the example embodiment illustrated in FIG. 2, unlike the example embodiment illustrated in FIG. 1, each of the plurality of memory structures S1, S2, and S3 may not include a sub-interposer 130. In the example embodiment illustrated in FIG. 2, the buffer die 140a may replace the role of the sub-interposer 130 of the example embodiment illustrated in FIG. 1.

A plurality of buffer lower pads 142 may be positioned on the lower surface of the buffer die 140a, and a plurality of buffer connection members 141 may be positioned on the plurality of buffer lower pads 142. The buffer die 140a may be connected to a component positioned at the lower portion of the buffer die 140a by the plurality of buffer lower pads 142 and the plurality of buffer connection members 141. A plurality of buffer upper pads 148 may be positioned on the upper surface of the buffer die 140a. The buffer die 140a may be connected to a component positioned above the buffer die 140a by the plurality of buffer upper pads 148.

Each of the buffer connection member 141, the buffer lower pad 142, and the buffer upper pad 148 may include a conductive material. For example, each of the buffer connection member 141, the buffer lower pad 142, and the buffer upper pad 148 may include a metal such as copper, aluminum, or an alloy thereof. For example, the buffer connection member 141 may be a solder ball.

The plurality of memory dies 140b_1, 140b_2, and 140b_3 may be bonded on the upper surface of buffer die 140a. A plurality of memory lower pads 152 may be positioned on the lower surface of the first lowermost memory die 140b_1 among the plurality of memory dies 140b_1, 140b_2, and 140b_3, and a plurality of memory connection members 151 may be positioned on the plurality of memory lower pad 152, respectively. The plurality of memory dies 140b_1, 140b_2, and 140b_3 may be connected to the buffer die 140a by the plurality of memory lower pad 152 and the plurality of memory connection members 151. The plurality of memory lower pads 152 may be connected to at least a portion of the plurality of buffer upper pads 148 positioned on the upper surface of the buffer die 140a by the plurality of memory connection members 151.

The first lowermost memory die 140b_1 among the plurality of memory dies 140b_1, 140b_2, and 140b_3 may be electrically connected to the buffer die 140a through the plurality of memory lower pad 152 and the plurality of memory connection members 151. Among the plurality of memory dies 140b_1, 140b_2, and 140b_3, the second memory die 140b_2 and the third memory die 140b_3 positioned above the first memory die 140b_1 may be electrically connected to the buffer die 140a through the die through via 145.

In some example embodiments, the size of the buffer die 140a may be larger than the sizes of the plurality of memory dies 140b_1, 140b_2, and 140b_3. The molding member 160 may cover the side surfaces of the plurality of memory dies 140b_1, 140b_2, and 140b_3 on the upper surface of the buffer die 140a. The molding member 160 may cover the upper surface of the buffer die 140a. The molding member 160 may be positioned between the upper surface of the buffer die 140a and the lower surface of the first lowermost memory die 140b_1 among the plurality of memory dies 140b_1, 140b_2, and 140b_3. The molding member 160 may cover the plurality of buffer upper pad 148, the plurality of memory lower pad 152, and the plurality of memory connection members 151. The molding member 160 may cover the upper surface of the uppermost third memory die 140b_3 among the plurality of memory dies 140b_1, 140b_2, and 140b_3, but example embodiments are not limited thereto. According to some example embodiments, the upper surface of the molding member 160 may be positioned at substantially the same level as the upper surface of the uppermost memory die among the plurality of memory dies 140b_1, 140b_2, and 140b_3.

In the example embodiment illustrated in FIG. 2, unlike the example embodiment illustrated in FIG. 1, the plurality of mold lower pads (162 in FIG. 1) may not be positioned on the lower surface of the molding member 160. The mold through via MV may connect the mold upper pad 168 and the buffer upper pad 148 in the vertical direction (e.g., the third direction DR3) to the upper surface of the substrate 110 by penetrating the molding member 160. In the example embodiment illustrated in FIG. 2, the molding member 160 is illustrated as being in contact with the upper surface of the buffer die 140a, but example embodiments are not limited thereto, and may be spaced apart from the upper surface of the buffer die 140a, such as in FIG. 1 where the molding member 160 is spaced apart from the upper surface of the sub-interposer 130.

In some example embodiments, the through vias TV penetrating the plurality of memory structures S1, S2, and S3 may include a buffer through via BV penetrating the buffer die 140a. The buffer through via BV may connect the buffer lower pad 142 positioned on the lower surface of a buffer die 140a and the buffer upper pad 148 positioned on the upper surface of the buffer die 140a in the vertical direction (e.g., the third direction DR3) to the upper surface of the substrate 110.

The buffer through via BV may include a conductive material. For example, the buffer through via BV may include a metal such as copper, aluminum, or an alloy thereof. In some example embodiments, the buffer through via BV may electrically connect the mold through vias MV that are spaced apart in the vertical direction (e.g., the third direction DR3) to the upper surface of the main interposer 120. The buffer through via BV may be electrically connect the mold through via MV to the main interposer 120. The buffer through via BV may electrically connect the plurality of memory dies 140b_1, 140b_2, and 140b_3 of the lowermost memory structure to the main interposer 120.

In some example embodiments, the buffer through via BV may include a first buffer through via BV1 penetrating the buffer die 140a of the first memory structure S1 and a second buffer through via BV2 penetrating the buffer die 140a of the second memory structure S2. Although not shown, the buffer through via BV may include a third buffer through via that passes through the buffer die 140a of the third memory structure S3.

In some example embodiments, a plurality of buffer through vias BV may be provided penetrating one buffer die 140a. For example, a plurality of first buffer through vias BV1 and a plurality of second buffer through vias BV2 may be provided. Each of the plurality of buffer through via BVs penetrating one buffer die 140a may be electrically connected to one of at least one memory structure positioned above the memory structure through which the plurality of buffer through vias BV penetrate. That is, each of the plurality of buffer through via BVs penetrating one buffer die 140a is not shared by the multiple memory structures, but may only be used by one memory structure. That is, the plurality of buffer through via BV penetrating one buffer die 140a may transmit and receive signals of each memory structure positioned above the memory structure penetrated by the plurality of the buffer through via BV in parallel.

In some example embodiments, at least one buffer through via BV may be aligned to the buffer through via BV in the direction (e.g., the third direction DR3) perpendicular to the upper surface of the substrate 110. At least one buffer through via BV may be aligned in the third direction DR3 with the mold through via MV positioned at the upper and/or lower side of the buffer die 140a through which the buffer through via BV passes. The alignment of the buffer through via BV and the mold through via MV along the third direction DR3 may mean, for example, that the central axis of the buffer through via BV and the central axis of the mold through via MV along the third direction DR3 are approximately aligned.

In some example embodiments, at least one buffer through via BV may connect the mold through vias MV that are spaced in the direction (e.g., the third direction DR3) vertical to the upper surface of the main interposer 120. For example, the first mold through via MV1 and the second mold through via MV2 may be separated in the third direction DR3, and at least one second buffer through via BV2 may connect the first mold through via MV1 and the second mold through via MV2, which are separated in the third direction DR3. At least one second buffer through via BV2 may be aligned in the third direction DR3 with the first mold through via MV1 and the second mold through via MV2 connected by the second buffer through via BV2.

In some example embodiments, at least one buffer through via BV may connect the lowermost mold through via among the plurality of mold through via MVs and the main interposer 120. For example, among the first mold through via MV1 and the second mold through via MV2, the first mold through via MV1 may be positioned at the lowermost position, and at least one first buffer through via BV1 may connect the first mold through via MV1 and the main interposer 120. At least one first buffer through via BV1 may be aligned in the third direction DR3 with the first mold through via MV1 connected to the substrate 110 by the first buffer through via BV1.

In some example embodiments, the lowermost memory structure among the plurality of memory structures S1, S2, and S3 may be connected to the main interposer 120 by the buffer through via BV, the buffer lower pad 142, and the buffer connection member 141. At least one buffer through via BV may connect the plurality of memory dies 140b_1, 140b_2, and 140b_3 of the lowermost memory structure and the main interposer 120. The buffer die 140a of the lowermost memory structure may be connected to the main interposer 120 by the buffer lower pad 142 and the buffer connection member 141. For example, the first memory structure S1 may be connected to the main interposer 120 by at least one first buffer through via BV1, at least one buffer lower pad 142, and at least one buffer connection member 141. At least one first buffer through via BV1 may connect the plurality of memory dies 140b_1 and 140b_2 of the first memory structure S1 and the main interposer 120. The buffer die 140a of the first memory structure S1 may be connected to the main interposer 120 by buffer lower pad 142 and the buffer connection member 141.

Although not shown, each of the buffer die 140a of the plurality of memory structures S1, S2, and S3 may include a wiring layer. The wiring layer of the buffer die 140a may connect the plurality of buffer lower pads 142 positioned on the lower surface of the buffer die 140a and the plurality of buffer upper pads 148 positioned on the upper surface of the buffer die 140a.

Referring to the first signal path SP1, a signal may be transmitted/received between the main interposer 120 and the first memory structure S1 through the first buffer through via BV1. Referring to the second signal path SP2, a signal may be transmitted/received between the main interposer 120 and the second memory structure S2 through the first mold via MV1 and the first buffer via BV1. Referring to the third signal path SP3, a signal may be transmitted/received between the main interposer 120 and the third memory structure S3 through the second mold via MV2, the second buffer via BV2, the first mold via MV1, and the first buffer via BV1. The signals transmitted to the main interposer 120 may be transmitted to the first semiconductor chip 10 or the substrate 110 through the wiring layer and/or the through via of the main interposer 120.

According to some example embodiments, the first signal path SP1, the second signal path SP2, and the third signal path SP3 may not overlap. As described above, each mold through via MV and each buffer through via BV may be connected to only one of the plurality of memory structures. That is, the mold through via MV and the buffer through via BV used in the first signal path SP1, the mold through via MV and the buffer through via BV used in the second signal path SP2, and the mold through via MV and the buffer through via BV used in the third signal path SP3 may not overlap each other. Accordingly, the plurality of memory structures S1, S2, and S3 may communicate in parallel with the first semiconductor chip 10, and the bandwidth of the semiconductor package may be dramatically increased.

In some example embodiments, the lowermost memory die among the plurality of memory dies 140b_1, 140b_2, and 140b_3 may be a master die, and the remaining memory dies may be slave dies. In the example embodiment illustrated in FIG. 2, the master die and the slave die are depicted as having the same size, but this is not limited to the example embodiment, and the master die may be larger than the slave die. In some example embodiments, the master die may include an interface circuit, control a communication between the slave dies and performs a communication with an external memory controller through the interface circuit. In this case, the buffer die 140a does not include an interface circuit and may only perform the role of an interposer. In some example embodiments, each of the plurality of memory structures S1, S2, and S3 may be a stacked memory in which the plurality of memory dies 140b_1, 140b_2, and 140b_3 including a master die including an interface circuit and at least one slave die are stacked on a buffer die 140a that performs only an interposer role. The stacked memory may be, for example, a stacked DRAM.

However, it is not limited to the example embodiment described above. According to some example embodiments, some of the plurality of memory structures S1, S2, and S3 may be high-bandwidth memories (HBMs) in which the plurality of memory dies 140b_1, 140b_2, and 140b_3 are stacked on the buffer die 140a including an interface circuit. In some example embodiments, some of the plurality of memory structures S1, S2, and S3 may be the HBM and others may be the stacked DRAM.

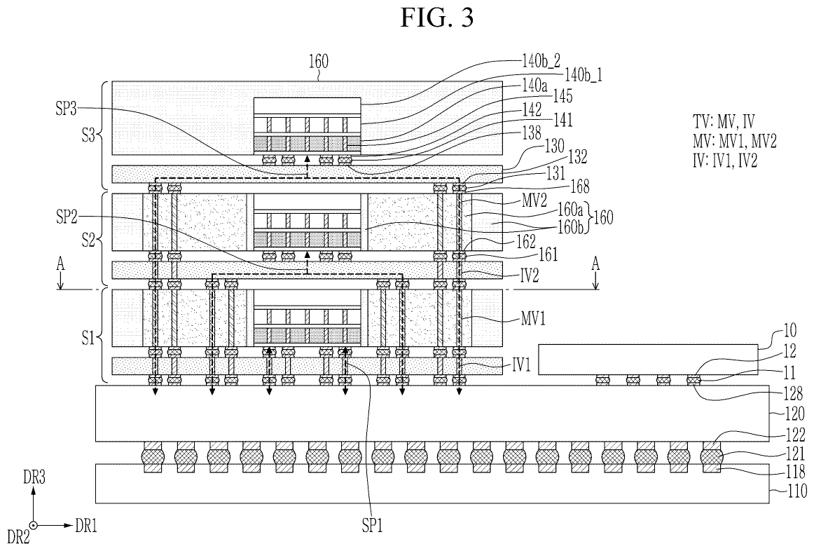

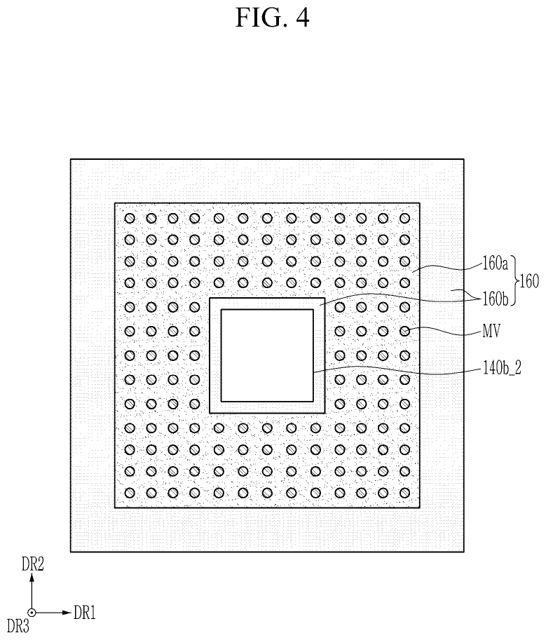

Below, variations of the semiconductor package according to the example embodiment of FIG. 1 are described with reference to FIG. 3 and FIG. 4,

FIG. 3 is a cross-sectional view of a semiconductor package according to some example embodiments. FIG. 4 is a top plan view of a semiconductor package as seen from the level of a line A-A′ of FIG. 3. The example embodiments illustrated in FIG. 3 and FIG. 4 are substantially the same as the example embodiment illustrated in FIG. 1, so a description thereof will be omitted and the differences will be mainly explained. Additionally, the same reference numerals are used for the same components as in the previous embodiment. The example embodiments illustrated in FIG. 3 and FIG. 4 may differ from the previous embodiments in that each of the molding members 160 of the plurality of memory structures S1, S2, and S3 includes a first molding member 160a and a second molding member 160b.

The semiconductor package according to some example embodiments, as shown in FIG. 3 and FIG. 4, may include a substrate 110, a main interposer 120 positioned on the substrate 110, and a first semiconductor chip 10 and a plurality of memory structures S1, S2, and S3 positioned on the main interposer 120. In some example embodiments, each of the plurality of memory structures S1, S2, and S3 may include a buffer die 140a, a plurality of memory dies 140b_1, 140b_2, and 140b_3 stacked on the buffer die 140a, and a molding member 160 covering the buffer die 140a and the plurality of memory dies 140b_1, 140b_2, and 140b_3. The example embodiments illustrated in FIG. 3 and FIG. 4 may, unlike the example embodiment illustrated in FIG. 1, include a first molding member 160a and a second molding member 160b.

In some example embodiments, the first molding member 160a may surround the side surfaces of the buffer die 140a and the plurality of memory dies 140b_1 and 140b_2. The buffer die 140a and the plurality of memory dies 140b_1 and 140b_2 may be positioned inside the space surrounded by the first molding member 160a. The second molding member 160b may be positioned between the side surface of the buffer die 140a and the plurality of memory dies 140b_1 and 140b_2 and the side surface of the first molding member 160a. The second molding member 160b may fill the remaining space in the space surrounded by the first molding member 160a, where the buffer die 140a and a plurality of memory dies 140b_1 and 140b_2 are positioned. The second molding member 160b may cover the side surface of the first molding member 160a. The second molding member 160b may surround the side surface of the first molding member 160a. Among the plurality of memory dies 140b_1 and 140b_2, the top die (e.g., the second memory die 140b_2) may be covered only by the second molding member 160b.

The second molding member 160b may include a thermosetting resin such as an epoxy resin, a thermoplastic resin such as a polyimide, a resin containing inorganic fillers and/or glass fibers, or an epoxy molding compound (EMC). However, example embodiments are not limited thereto.

In some example embodiments, the first molding member 160a may include a different material than the second molding member 160b. The first molding member 160a may include a harder material than the second molding member 160b, and the surfaces (e.g., the upper surface and/or lower surface) of the first molding member 160a may be flatter than the surfaces (e.g., the upper surface and/or lower surface) of the second molding member 160b. The first molding member 160a may, for example, include glass, but example embodiments are not limited thereto.

In some example embodiments, the plurality of mold upper pads 168 may be positioned on the upper surface of the first molding member 160a, and the plurality of mold lower pads 162 may be positioned on the lower surface of the first molding member 160a. The mold through via MV may connect the mold upper pad 168 and the mold lower pad 162 in the direction perpendicular to the upper surface of the substrate 110 (e.g., the third direction DR3). In some example embodiments, the mold through via MV may penetrate the first molding member 160a.

According to some example embodiments, the first molding member 160a through which the mold through via MV penetrates may include a harder material than the second molding member 160b, for example glass. Accordingly, the mold through via MV penetrating the first molding member 160a may be formed with a finer width and spacing. Additionally, the upper and lower surfaces of the first molding member 160a may be flatter than the upper and lower surfaces of the second molding member 160b, and. the mold upper pad 168 and the mold lower pad 162 can be more easily formed on the upper surface and lower surface of the first molding member 160a than on the upper surface and lower surface of the second molding member 160b.

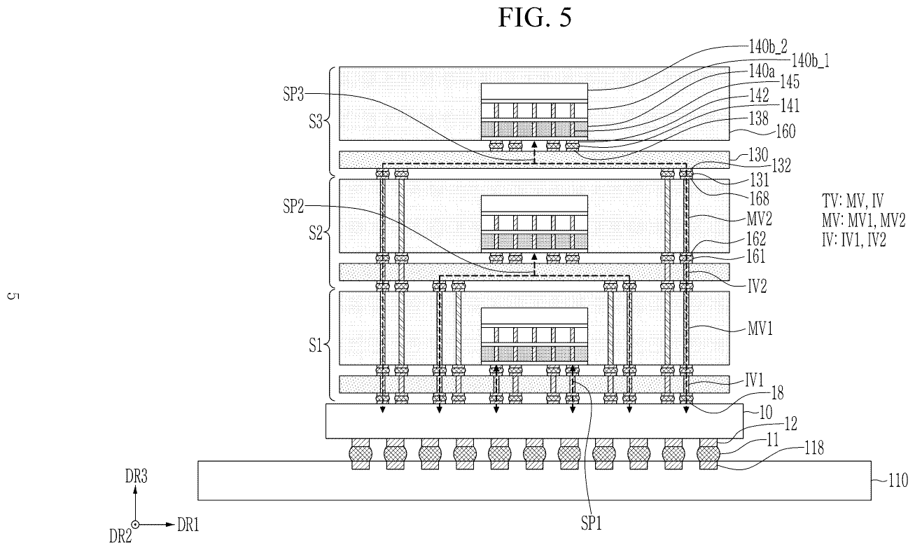

Below, a variation of the semiconductor package according to the example embodiment of FIG. 1 is described with reference to FIG. 5.

FIG. 5 is a cross-sectional view of a semiconductor package according to some example embodiments. The example embodiment illustrated in FIG. 5 is substantially the same as the example embodiment illustrated in FIG. 1, so a description thereof will be omitted and the differences will be mainly explained. Additionally, the same reference numerals are used for the same components as in the previous example embodiment. The example embodiment illustrated in FIG. 5 may differ from the previous example embodiment in that the main interposer 120 is omitted.

A semiconductor package according to some example embodiments, as shown in FIG. 5, may include a substrate 110, a first semiconductor chip 10 and a plurality of memory structures S1, S2, and S3 positioned on the substrate 110. In some example embodiments, each of the plurality of memory structures S1, S2, and S3 may include a buffer die 140a, a plurality of memory dies 140b_1, 140b_2, and 140b_3 stacked on the buffer die 140a, and a molding member 160 covering the buffer die 140a and the plurality of memory dies 140b_1, 140b_2, and 140b_3. In the example embodiment illustrated in FIG. 5, unlike the example embodiment illustrated in FIG. 1, the plurality of memory structures S1, S2, and S3 may be stacked on the first semiconductor chip 10.

In some example embodiments, the first semiconductor chip 10 may be positioned between the plurality of memory structures S1, S2, and S3 and the substrate 110. The plurality of memory structures S1, S2, and S3 may be positioned on the first semiconductor chip 10. The plurality of memory structures S1, S2, and S3 may be arranged on the first semiconductor chip 10 in the vertical direction (e.g., the third direction DR3) to the upper surface of the substrate 110. The plurality of memory structures S1, S2, and S3 may be stacked in the third direction DR3 on the upper surface of the first semiconductor chip 10.

In some example embodiments, the plurality of seventh connection pads 18 may be positioned on the upper surface of the first semiconductor chip 10. The plurality of fifth connection pads 132 positioned on the lower surface of the sub-interposer 130 of the first memory structure S1, which is the lowermost memory structure among the plurality of memory structures S1, S2, and S3, may be connected to the plurality of seventh connection pads 18 by the plurality of third connection members 131.

The description referring to be connected to the main interposer 120 among the description with reference to FIG. 1 may be applied identically to the example embodiment illustrated in FIG. 5 by only changing the connection target to the first semiconductor chip 10. For example, the mold through via MV and the interposer through via IV may connect the plurality of memory structures S1, S2, and S3 to the first semiconductor chip 10 in the third direction DR3.

Although not shown, the first semiconductor chip 10 may include a wiring layers and/or a through via connecting the plurality of seventh connection pads 18 and the plurality of fourth connection pads 12. For example, the plurality of memory structures S1, S2, and S3 may be connected to the substrate 110 by a wiring layer and/or a through via of the first semiconductor chip 10.

According to the example embodiment illustrated in FIG. 5, the distance between each of the plurality of memory structures S1, S2, and S3 and the first semiconductor chip 10 may be shortened compared to the example embodiment illustrated in FIG. 1, so that the communication speed may be further improved.

In FIG. 5, the main interposer 120 is omitted from the structure of the semiconductor package according to the example embodiment of FIG. 1, and the plurality of memory structures S1, S2, and S3 are stacked on the first semiconductor chip 10, but example embodiments are not limited thereto. In the structure of the semiconductor package according to the example embodiment of FIG. 2 or FIG. 3, the main interposer 120 may be omitted, and the plurality of memory structures S1, S2, and S3 may be stacked on the first semiconductor chip 10.

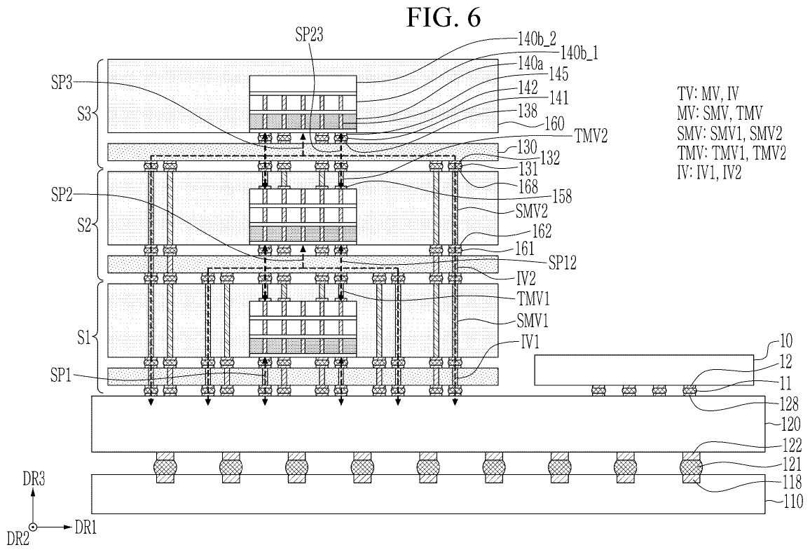

Below, a variation of the semiconductor package according to the example embodiment FIG. 1 is described with reference to FIG. 6.

FIG. 6 is a cross-sectional view of a semiconductor package according to some example embodiments. The example embodiment illustrated in FIG. 6 is substantially the same as the example embodiment illustrated in FIG. 1, so a description thereof will be omitted and the differences will be mainly explained. Additionally, the same reference numerals are used for the same components as in the previous embodiment. The example embodiment illustrated in FIG. 6 may differ from the previous embodiment in that the mold through via MV includes a side mold through via SMV and an upper mold through via TMV.

In some example embodiments, the side mold through via SMV may penetrate a portion of the molding member 160 covering the side surfaces of the plurality of memory dies 140b_1 and 140b_2. The side mold through via SMV may connect the mold upper pad 168 positioned on the upper surface of the molding member 160 and the mold lower pad 162 positioned on the lower surface of the molding member 160 in the direction (e.g., the third direction DR3) perpendicular to the upper surface of the substrate 110.

For example, the side mold through via SMV may include a first side mold through via SMV1 penetrating the molding member 160 of the first memory structure S1 and a second side mold through via SMV2 penetrating the molding member 160 of the second memory structure S2. Referring to the first signal path SP1, the second signal path SP2, and the third signal path SP3, a signal may be transmitted/received between the plurality of memory structures S1, S2, and S3 and the main interposer 120 through the side mold through via SMV. The signal transmitted to the main interposer 120 may be transmitted to the first semiconductor chip 10 or the substrate 110 through the wiring layer and/or the through via of the main interposer 120. The plurality of memory structures S1, S2, and S3 may be electrically connected to the first semiconductor chip 10 and the substrate 110 through side mold through via SMV.

In some example embodiments, the upper mold through via TMV may penetrate a portion of the molding member 160 covering the upper surface of the uppermost memory die (e.g., a second memory die (140b_2)) among the plurality of memory dies 140b_1 and 140b_2. The plurality of memory upper pads 158 may be positioned on the upper surface of the uppermost memory die (e.g., the second memory die (140b_2)) of the plurality of memory dies 140b_1 and 140b_2. The upper mold through via TMV may connect the mold upper pad 168 positioned on the upper surface of the molding member 160 and the plurality of memory upper pad 158 positioned on the upper surface of the uppermost memory die (for example: the second memory die 140b_2) covered by the molding member 160 in the direction (for example, the third direction DR3) vertical to the upper surface of the substrate 110. The upper mold through via TMV may penetrate the molding member 160 of the remaining memory structures except for the uppermost memory structure among the plurality of memory structures S1, S2, and S3.

For example, the upper mold through via TMV may include a first upper mold through via TMV1 penetrating the molding member 160 of the first memory structure S1 and a second upper mold through via TMV2 penetrating the molding member 160 of the second memory structure S2. Referring to the fourth signal path SP12, a signal may be transmitted/received between the first memory structure S1 and the second memory structure S2 through the first upper mold through via TMV1. Referring to the fifth signal path SP23, a signal may be transmitted/received between the second memory structure S2 and the third memory structure S3 through the second upper mold through via TMV2. That is, the plurality of memory structures S1, S2, and S3 may be electrically connected to each other through the first upper mold via TMV1 and the second upper mold via TMV2.

According to the example embodiment illustrated in FIG. 6, the plurality of memory structures S1, S2, and S3 may communicate directly through the first upper mold via TMV1 and the second upper mold via TMV2 without going through the first semiconductor chip 10, thereby improving a communication speed of the semiconductor package and/or reducing a power consumption.

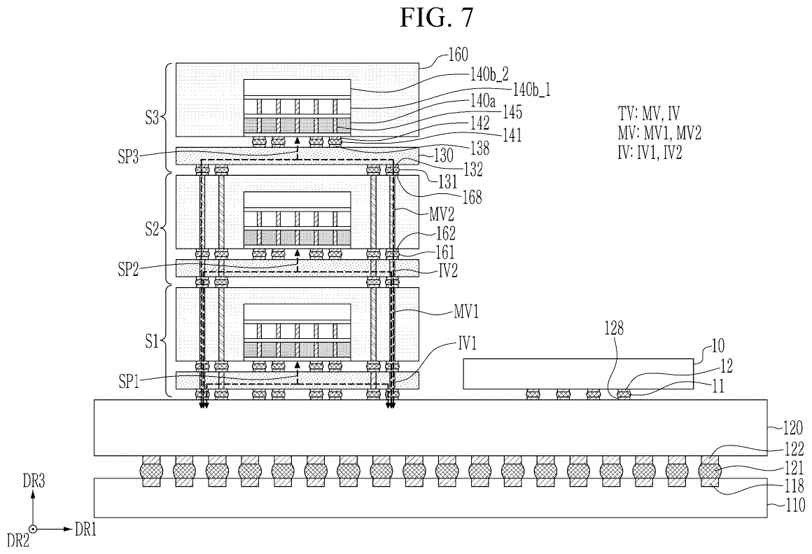

Below, a variation of the semiconductor package according to the example embodiment of FIG. 1 are described with reference to FIG. 7.

FIG. 7 is a cross-sectional view of a semiconductor package according to some example embodiments. The example embodiment illustrated in FIG. 7 is substantially the same as the example embodiment illustrated in FIG. 1, so a description thereof will be omitted and the differences will be mainly explained. Additionally, the same reference numerals are used for the same components as in the previous embodiment. The example embodiment illustrated in FIG. 7 may differ from the previous embodiment in that the through via TV is electrically connected to at least one memory structure positioned above the through via TV.

In some example embodiments, a plurality of mold through vias MV may be provided penetrating one molding member 160. In the example embodiment shown in FIG. 7, unlike the example embodiment shown in FIG. 1, each of the plurality of mold through vias MV penetrating one molding member 160 may be electrically connected to at least one memory structure positioned above the memory structure through which the plurality of mold through via MVs penetrate. That is, each of the plurality of mold through via MVs penetrating one molding member 160 may be shared by the multiple memory structures. That is, the plurality of mold through via MV penetrating one molding member 160 may transmit and receive only one signal among at least one memory structure positioned above the memory structure penetrated by the plurality of mold through via MV at a time.

In some example embodiments, a plurality of mold through vias MV penetrating each of the plurality of molding members 160 may be provided. For example, the plurality of mold through via MV may include a first mold through via MV1 penetrating the molding member 160 of the first memory structure S1 and the second mold through via MV2 penetrating the molding member 160 of the second memory structure S2. In the example embodiment illustrated in FIG. 7, unlike the example embodiment illustrated in FIG. 1, the number of the first mold through vias MV1 may be equal to or substantially equal to the number of the second mold through vias MV2.

In some example embodiments, the second mold through via MV2 may be aligned to the first mold through via MV1 in a direction perpendicular to the upper surface of the substrate 110 (e.g., the third direction DR3). In some example embodiments, each of the plurality of second mold through via MV2 may be aligned to each of the plurality of first mold through via MV1 in a direction (e.g., the third direction DR3) perpendicular to the upper surface of the substrate 110.

In some example embodiments, a plurality of interposers through via IV that penetrate one sub-interposer 130 may be provided. In the example embodiment shown in FIG. 7, unlike the example embodiment shown in FIG. 1, each of the plurality of interposer through vias IV penetrating one sub-interposer 130 may be electrically connected to at least one memory structure positioned above the memory structure penetrating the plurality of interposer through vias IV. That is, each of the plurality of interposer through vias IV penetrating one sub-interposer 130 may be shared by the multiple memory structures. That is, the plurality of interposer through vias IV penetrating one sub-interposer 130 may transmit and receive a signal from only one memory structure positioned above the memory structure penetrated by the plurality of interposer through vias IV at a time.

In some example embodiments, a plurality of first interposer through via IV1 penetrating the sub-interposer 130 of the first memory structure S1 and a plurality of second interposer through via IV2 penetrating the sub-interposer 130 of the second memory structure S2 may be provided. At least one second interposer through via IV2 may connect the second mold through via MV2 and the first mold through via MV1. At least one first interposer through via IV1 may connect the first mold through via MV1 and the main interposer 120. At least one first interposer through via IV1 may connect the sixth connection pad 138 positioned on the upper surface of the sub-interposer 130 of the lowermost memory structure (e.g., the first memory structure S1) and the fifth connection pad 132 positioned on the lower surface of the sub-interposer 130. In the example embodiment shown in FIG. 7, unlike the example embodiment shown in FIG. 1, the number of the first interposer through via IV1 connecting the first mold through via MV1 and the main interposer 120 may be equal to or substantially equal to the number of the second interposer through via IV2 connecting the second mold through via MV2 and the first mold through via MV1.

According to some example embodiments, the first signal path SP1, the second signal path SP2, and the third signal path SP3 may overlap. As described above, each mold through via MV and each interposer through via IV may be connected to the plurality of entire memory structures. That is, the mold through via MV and the interposer through via IV used in the first signal path SP1, the mold through via MV and the interposer through via IV used in the second signal path SP2, and the mold through via MV and the interposer through via IV used in the third signal path SP3 may overlap. Accordingly, the plurality of memory structures S1, S2, and S3 may communicate with the first semiconductor chip 10 through the smaller number of the mold through-vias MV and the interposer through-vias IV than in the example embodiment illustrated in FIG. 1.

According to the example embodiment illustrated in FIG. 7, the number of the mold through vias MV and the interposer through vias IV is smaller than that of the example embodiment illustrated in FIG. 1, so that the size (or a planar area) of the sub-interposer 130 and the molding member 160 may be reduced, and thus the size of the semiconductor package may be reduced.

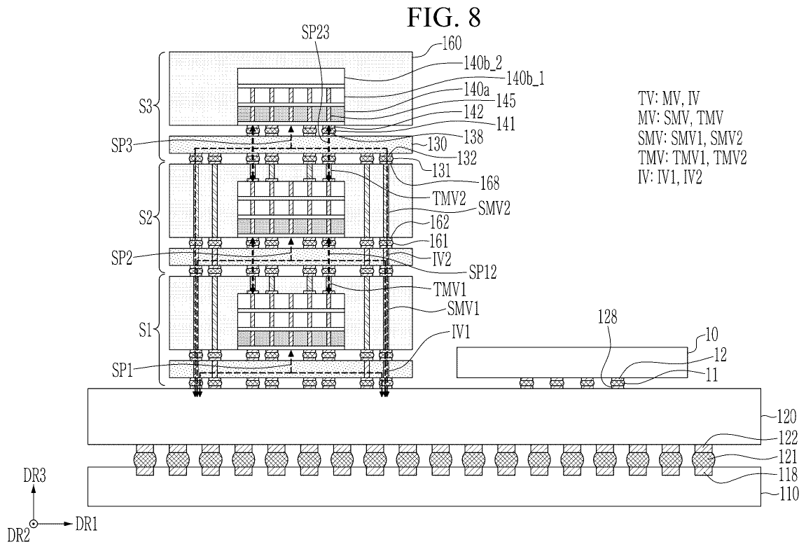

Below, a variation of the semiconductor package according to the example embodiment of FIG. 7 is described with reference to FIG. 8.

FIG. 8 is a cross-sectional view of a semiconductor package according to some example embodiments. The example embodiment illustrated in FIG. 8 is substantially the same as the example embodiment illustrated in FIG. 7, so a description thereof will be omitted and the differences will be mainly explained. Additionally, the same reference numerals are used for the same components as in the previous embodiment. The example embodiment illustrated in FIG. 8 may differ from the previous embodiment in that the mold through via MV includes a side mold through via SMV and an upper mold through via TMV.

In some example embodiments, the side mold through via SMV may penetrate a portion of the molding member 160 covering the side surfaces of the plurality of memory dies 140b_1 and 140b_2. The side mold through via SMV may connect the mold upper pad 168 positioned on the upper surface of the molding member 160 and the mold lower pad 162 positioned on the lower surface of the molding member 160 in a direction (e.g., the third direction DR3) perpendicular to the upper surface of the substrate 110. For example, the side mold through via SMV may include a first side mold through via SMV1 penetrating the molding member 160 of the first memory structure S1 and a second side mold through via SMV2 penetrating the molding member 160 of the second memory structure S2. For the first side mold through via SMV1 and the second side mold through via SMV2, the same description as referring to FIG. 7 may be applied.

In some example embodiments, the upper mold through via TMV may penetrate a portion of the molding member 160 covering the upper surface of the uppermost memory die (e.g., the second memory die (140b_2)) among the plurality of memory dies 140b_1 and 140b_2. The upper mold through via TMV may connect the plurality of memory upper pads 158 positioned on the upper surface of the molding member 160 and the uppermost memory die (e.g., the second memory die 140b_2) covered by the molding member 160 in a direction perpendicular to the upper surface of the substrate 110 (e.g., the third direction DR3). The upper mold through via TMV may penetrate the molding member 160 of the remaining memory structures except for the uppermost memory structure among the plurality of memory structures S1, S2, and S3. For example, the upper mold through via TMV may include a first upper mold through via TMV1 penetrating the molding member 160 of the first memory structure S1 and a second upper mold through via TMV2 penetrating the molding member 160 of the second memory structure S2.

In some example embodiments, with reference to the first signal path SP1, the second signal path SP2, and the third signal path SP3, signals may be transmitted/received between the plurality of memory structures S1, S2, and S3 and the main interposer 120 through the side mold through via SMV. The signal transmitted to the main interposer 120 may be transmitted to the first semiconductor chip 10 or the substrate 110 through the wiring layer and/or the through via of the main interposer 120. The plurality of memory structures S1, S2, and S3 may be electrically connected to the first semiconductor chip 10 and the substrate 110 through the side mold through via SMV.

In some example embodiments, referring to the fourth signal path SP12, a signal may be transmitted/received between the first memory structure S1 and the second memory structure S2 through the first upper mold via TMV1. Referring to the fifth signal path SP23, a signal may be transmitted/received between the second memory structure S2 and the third memory structure S3 through the second upper mold through via TMV2. That is, the plurality of memory structures S1, S2, and S3 may be electrically connected to each other through the first upper mold via TMV1 and the second upper mold via TMV2.

According to the example embodiment illustrated in FIG. 8, the plurality of memory structures S1, S2, and S3 may communicate directly through the third mold via MV12 and the fourth mold via MV23 without going through the first semiconductor chip 10, thereby improving the communication speed of the semiconductor package and/or reducing the power consumption.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While some example embodiments of this disclosure have been described in connection with what is presently considered to be practical example embodiments, it is to be understood that the disclosure is not limited to the disclosed example embodiments, but, on the contrary, is intended to cover various modifications and equivalent arrangements included within the spirit and scope of the appended claims.

What is claimed is:

1. A semiconductor package comprising:
a substrate;
a first semiconductor chip and a plurality of memory structures on the substrate; and
a through via penetrating at least one of the plurality of memory structures,
wherein the plurality of memory structures are stacked in a vertical direction, the vertical direction being perpendicular to an upper surface of the substrate,
each of the plurality of memory structures includes
a buffer die,
a plurality of memory dies stacked on the buffer die, and
a molding member covering the buffer die and the plurality of memory dies, and
the through via includes a mold through via that penetrates the molding member.

2. The semiconductor package of claim 1, wherein
the through via is included in a plurality of through vias,
each of the plurality of through vias penetrates at least one among the plurality of memory structures and electrically connects to at least one respective memory structure above.

3. The semiconductor package of claim 1, wherein
the mold through via penetrates each molding member of the plurality of memory structures excluding an uppermost memory structure of the plurality of memory structures.

4. The semiconductor package of claim 1, wherein
the plurality of memory structures includes
a first memory structure,
a second memory structure, and
a third memory structure sequentially stacked on the substrate,
the mold through via includes a first mold through via and a second mold through via connected to the third memory structure,
the first mold through via penetrates the molding member of the first memory structure, and the second mold through via penetrates the molding member of the second memory structure, and
the first mold through via and the second mold through via are aligned in a vertical direction.

5. The semiconductor package of claim 1, further comprising:
a main interposer between the substrate and the first semiconductor chip, and between the substrate and the plurality of memory structures; and
the first semiconductor chip and the plurality of memory structures are arranged on the main interposer in a horizontal direction, the horizontal direction being parallel to an upper surface of the main interposer.

6. The semiconductor package of claim 5, wherein
each of the plurality of memory structures further includes a sub-interposer,
the buffer die and the plurality of memory dies are on the sub-interposer, and
the through via further includes an interposer through via penetrating the sub-interposer.

7. The semiconductor package of claim 6, wherein
the interposer through via includes a plurality of interposer through vias, and
at least one interposer through via of the plurality of interposer through vias is aligned to the mold through via in the vertical direction.

8. The semiconductor package of claim 7, wherein
the mold through via is included in a plurality of mold through vias,
the plurality of mold through vias connect at least one of the plurality of memory structures to the main interposer, and
at least one interposer through via of the plurality of interposer through vias connects, in a direction perpendicular to the upper surface of the main interposer, between the plurality of mold through vias and between a lowermost mold through via among the plurality of mold through vias and the main interposer.

9. The semiconductor package of claim 6, wherein
the interposer through via includes a plurality of interposer through vias, and
a lowermost memory structure among the plurality of memory structures is connected to the main interposer by at least one interposer through via of the plurality of interposer through vias.

10. The semiconductor package of claim 5, wherein
the through via further includes a plurality of buffer through vias penetrating a buffer die of each of the plurality of memory structures.

11. The semiconductor package of claim 10, wherein
the mold through via is included in a plurality of mold through vias,
the plurality of mold through vias connect at least one of the plurality of memory structures to the main interposer, and
the plurality of buffer through vias connects, in a perpendicular to the upper surface of the main interposer, between the plurality of mold through vias and between a lowermost mold through via among the plurality of mold through vias and the main interposer.

12. The semiconductor package of claim 1, wherein
the buffer die and the plurality of memory dies for each of the plurality of memory structures are included in a die stack,
the molding member of each of the plurality of memory structures includes
a first molding member surrounding side surfaces of the die stack, and
a second molding member between side surfaces of the die stack and side surfaces of the first molding member,
the first molding member includes glass, and
the mold through via penetrates the first molding member.

13. The semiconductor package of claim 1, wherein
the first semiconductor chip is between the plurality of memory structures and the substrate, and
the plurality of memory structures is stacked on the first semiconductor chip.

14. The semiconductor package of claim 1, wherein
the mold through via includes
a side mold through via penetrating a portion of the molding member covering side surfaces of the plurality of memory dies, and
an upper mold through via penetrating a portion of the molding member covering the upper surface of an uppermost memory die among the plurality of memory dies,
the plurality of memory structures are electrically connected to the first semiconductor chip through the side mold through via, and the plurality of memory structures are electrically connected to each other through the upper mold through via.

15. The semiconductor package of claim 1, wherein
the through via is included in a plurality of through vias, and
each of the plurality of through vias penetrates at least one of the plurality of memory structures and electrically connects to at least one memory structure above.

16. A semiconductor package comprising:
a substrate;
a first semiconductor chip on the substrate;
a plurality of buffer dies and a plurality of memory dies on the substrate, such that at least two memory dies of the plurality of memory dies are stacked on one buffer die;
a plurality of molding members stacked on the substrate, each molding member of the plurality of molding members covering one buffer die of the plurality of buffer dies and at least two memory dies of the plurality of memory dies; and
at least one mold through via penetrating each molding member of the plurality of molding members except for an uppermost molding member among the plurality of molding members.

17. The semiconductor package of claim 16, wherein
the plurality of molding members includes a first molding member and a second molding member sequentially stacked on the substrate,
at least one mold through via includes a first mold through via penetrating the first molding member and a second mold through via penetrating the second molding member, and
the second mold through via is aligned to the first mold through via in a vertical direction, the vertical direction being perpendicular to an upper surface of the substrate.

18. The semiconductor package of claim 17, wherein
the first mold through via is included in a plurality of first mold through vias,
the second mold through via is included in a plurality of second mold through vias, and
a number of the plurality of first mold through vias is greater than a number of the plurality of second mold through vias.

19. The semiconductor package of claim 17, wherein
the first mold through via is included in a plurality of first mold through vias,
the second mold through via is included in a plurality of second mold through vias, and
a number of the first mold through vias is same as a number of the second mold through vias.

20. A semiconductor package comprising:
a substrate;
a first semiconductor chip on the substrate;
a plurality of memory structures stacked on the substrate, each memory structure of the plurality of memory structures including
a buffer die,
a plurality of memory dies stacked on the buffer die, and
a molding member covering the buffer die and the plurality of memory dies; and
a mold through via penetrating each molding member of the plurality of memory structures except for an uppermost memory structure among the plurality of memory structures,
wherein each memory structure of the plurality of memory structures is electrically connected to the first semiconductor chip through the mold through via.
